(19) United States
(12) Patent Application Publication
(10) Pub. No.: US 2023/0068627 A1
(43) Pub. Date: Mar. 2, 2023

(54) MULTI-LEVEL GATE DRIVER

(71) Applicant: Texas Instruments Incorporated, Dallas, TX (US)

(72) Inventors: Reza Sharifi, Santa Clara, CA (US); Ramesh Balan, Santa Clara, CA (US)

(21) Appl. No.: 17/894,003

(22) Filed: Aug. 23, 2022

Related U.S. Application Data
(60) Provisional application No. 63/236,579, filed on Aug. 24, 2021.

(51) Int. Cl. H02M 3/158; H03K 19/20; H03K 17/687; H03K 3/037

(52) U.S. Cl. CPC H02M 3/158; H03K 19/20; H03K 17/687; H03K 3/0377

(57) ABSTRACT

In one example, a switched circuit includes first and second transistors. The first transistor has a first gate and a first source/drain path. The second transistor has a second gate and a second source/drain path. The first and second source/drain paths are coupled in series between an input terminal and an output terminal. A first drive circuit has a first drive input and a first drive output. A second drive circuit has a second drive input and a second drive output. The first drive output is coupled to the first gate, and the second drive output is coupled to the second gate. Switching circuitry is coupled between: at least one of first or second power supply circuits; and at least one of the first or second drive circuits.

### CROSS-REFERENCE TO RELATED APPLICATION

This application claims the benefit of and priority to U.S. Provisional Patent Application No. 63/236,579 filed Aug. 24, 2021, which is hereby fully incorporated herein by reference.

### BACKGROUND

This description relates to a DC-DC converter.

DC-DC converters often include high frequency switching circuits to convert one DC voltage to a different DC voltage. Other converter design considerations include accurate regulation, noise minimization, and power efficiency, of the output DC voltage. Some of those considerations represent a tradeoff in view of another. For example, some conventional DC-DC converters regulate the output DC voltage by combining high voltage rails with linear regulation, using a closed feedback loop to maintain a fixed output DC voltage. However, that approach may introduce relatively large power loss, especially at lower duty cycles, where efficiency is already near a lower end of its range.

### SUMMARY

In one example, a switched circuit includes first and second transistors. The first transistor has a first gate and a first source/drain path. The second transistor has a second gate and a second source/drain path. The first and second source/drain paths are coupled in series between an input terminal and an output terminal. A first drive circuit has a first drive input and a first drive output. A second drive circuit has a second drive input and a second drive output. The first drive output is coupled to the first gate, and the second drive output is coupled to the second gate. Switching circuitry is coupled between: at least one of first or second power supply circuits; and at least one of the first or second drive circuits.

### BRIEF DESCRIPTION OF THE DRAWINGS

FIG. 1 is a schematic electrical diagram of an example switched DC-DC converter.

FIG. 2 is a switching diagram illustrating the FIG. 1 DC-DC converter operation and signal timing when the converter duty cycle, D, is less than 50%.

FIG. 3 is a switching diagram illustrating the FIG. 1 DC-DC converter operation and signal timing when the converter duty cycle, D, is greater than 50%.

FIG. 4 is a schematic electrical diagram of a first implementation of the FIG. 1 second voltage regulator 158.

FIG. 5 is a schematic electrical diagram of a second implementation of the FIG. 1 second voltage regulator 158.

### DETAILED DESCRIPTION

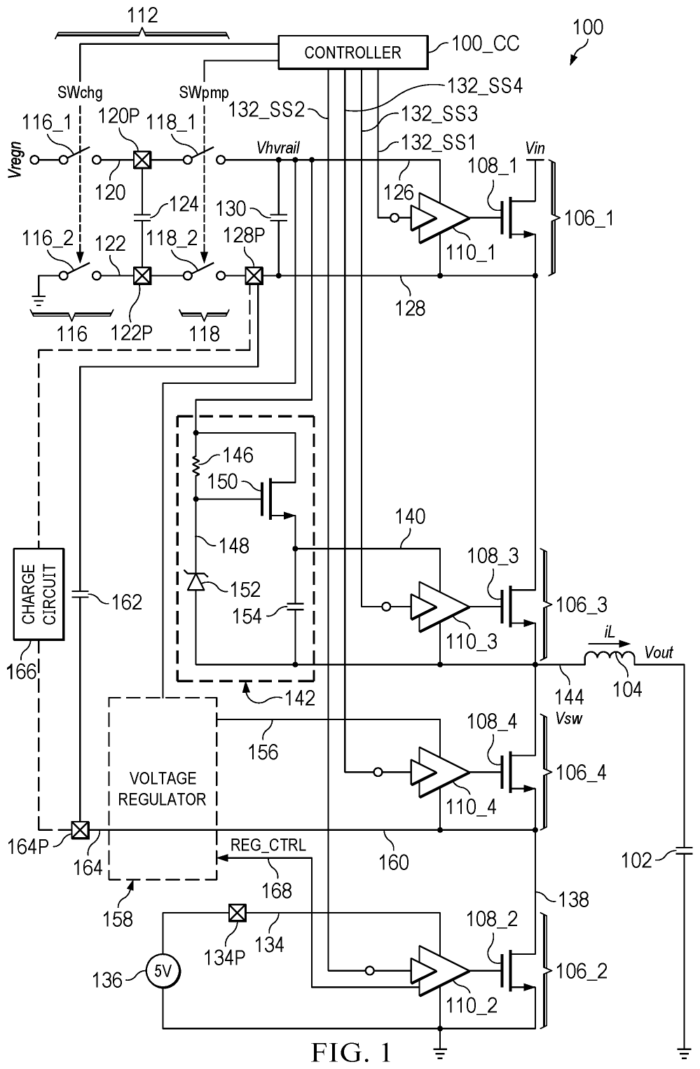

FIG. 1 is a schematic electrical diagram of an example switched DC-DC converter 100, having an input voltage Vin that is converted to a switched output voltage Vsw, from which is formed a filter output voltage Vout. More specifically, Vsw occurs at a node in a switched path described below, and it is filtered by the combination of an output capacitor 102 and an inductor 104, where Vout occurs across the output capacitor 102, which is connected to a first terminal of, and in series with, the inductor 104 through which a current iL passes. The output capacitor 102 and inductor 104 form an inductor-capacitor (LC) tank to convert (e.g., low pass filter) the switched output signal Vsw to the DC level of Vout. Generally, some portions of the DC-DC converter 100 may be formed as part of an integrated circuit (IC), while others are external devices. Also, for general reference but without limitation, the converter 100 includes a controller 100_CC, which sequences (among other things) level-determining circuits, which in the illustrated example are four, namely a first, second, third and fourth such circuit 106_1, 106_2, 106_3, and 106_4, respectively. Each level-determining circuit includes a respective first, second, third or fourth power transistor (e.g., field effect transistor (FET)) 108_1, 108_2, 108_3, and 108_4, with a source/drain terminal of each power transistor connected to a source/drain terminal of at least one other power transistor of the level-determining circuits. Each level-determining circuit also includes a respective first, second, third or fourth gate driver 110_1, 110_2, 110_3, and 110_4, each coupled to receive a positive and negative power supply voltage and to drive a respective one of the first through fourth power transistors 108_1 through 108_4. Generally, the level-determining circuits devices collectively operate so that Vsw may be one of three levels, such as Vsw equal to Vin, ground, or some voltage between Vin and ground (e.g., Vin/2). The controller 100_CC sequences those level-determining circuits, so: (a) an entire switching duration Tsw includes four intervals; (b) only two of the four level-determining circuits are on at a time during each interval; and (c) a relatively high voltage is provided during two of the intervals, and a relatively low voltage is provided during two of the intervals. Further, for each set of two of the four level-determining circuits that are on at a time during each interval, with one set including the first 106_1 and second 106_2 levels, and the other set including the third 106_3 and fourth 106_4 levels, within each set, the levels are complementary, meaning in each of those sets only one or the other of the level-determining circuits is on at a time. Still further, the converter duty cycle, D, is the ratio of when the first power transistor 108_1 is on, relative to the total switching duration Tsw, and D also determines the level of Vout according to Vin*D=Vout. Accordingly, for a fixed Vout, as Vin increases then D must decrease, although increasing Vin places a greater voltage difference along the path through the source-drains of the collective power transistors 108_1 through 108_4, which could decrease converter efficiency but is addressed in the converter 100 as described below. Also, the converter 100 includes a switched charging circuit 112 that couples to each of the four level-determining circuits 106_1, 106_2, 106_3, and 106_4. Each of the level-determining circuits 106_1, 106_2, 106_3, and 106_4, and the switched charging circuit 112, is further described below.

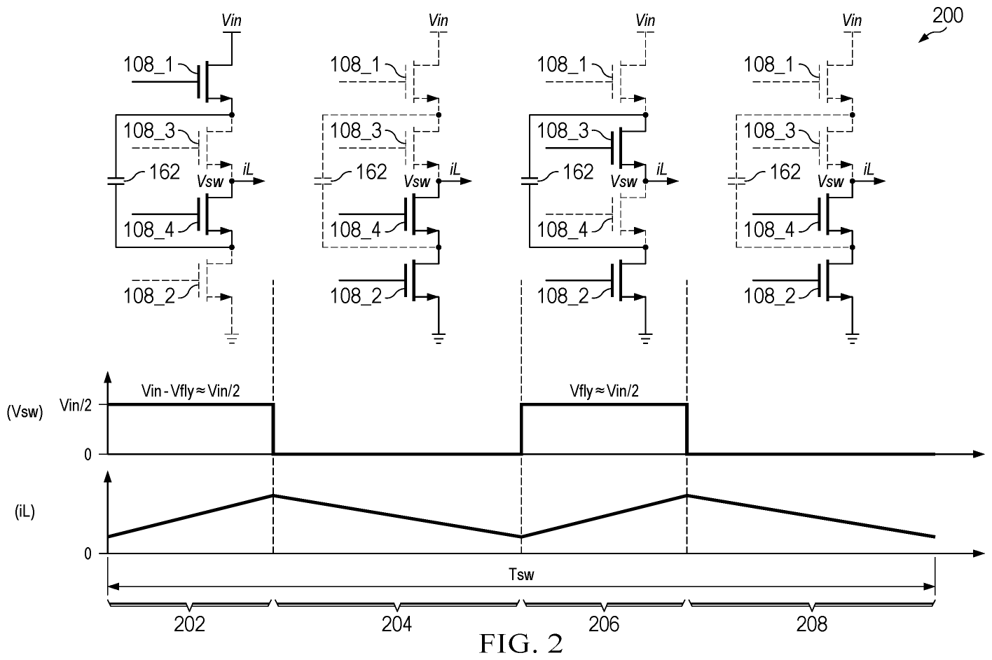

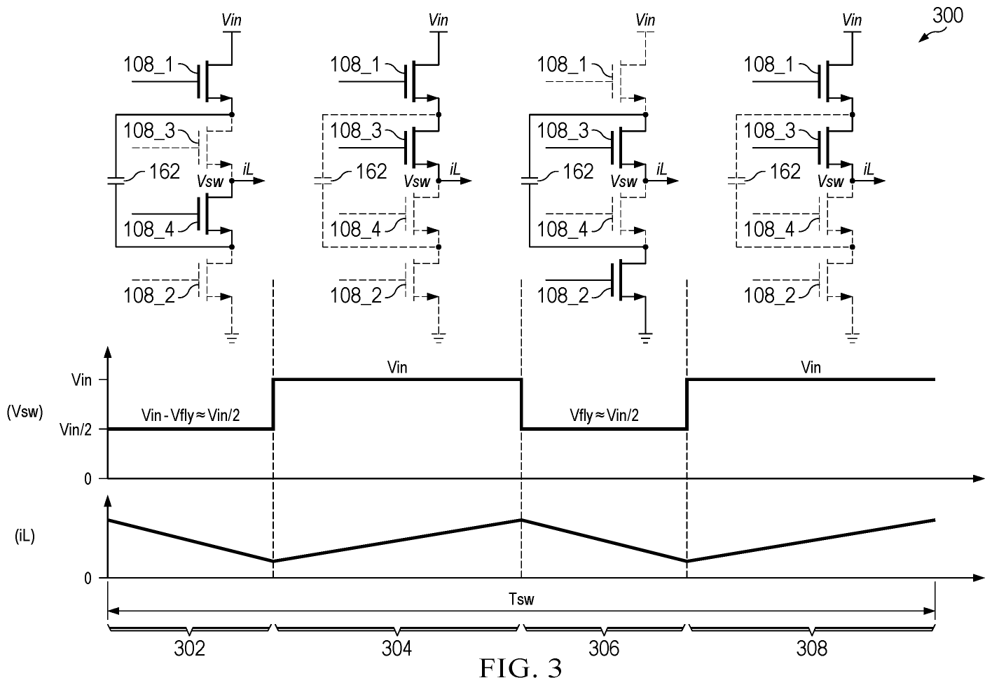

The switched charging circuit 112 includes a first switching pair 116 and a second switching pair 118. The first switching pair 116 includes a first switch 116_1 and a second switch 116_2, both controlled by a same charge switching signal SWchg from the converter controller 100_CC. The first and second switches 116_1 and 116_2 are shown using conventional schematic switch symbols, but may be implemented in various forms, including with one or more transistors in a switching path. A first terminal of the first switch 116_1 receives a regulated voltage Vregn, such as provided from a low dropout (LDO) supply. For example, Vregn may have a nominal value of 5.0 V. A second terminal of the first switch 116_1 is connected to a first node 120. The first node 120 electrically couples to a pin 120P that is represented schematically as shown (as are other pins) to physically represent the pin, and electrically equivalent to the node coupled to it, where the pin 120P is accessible externally from the IC that forms portions of the converter 100. A first terminal of the second switch 116_2 is coupled to a relatively low voltage, such as ground, and a second terminal of the second switch 116_2 is connected to a second node 122, which is also coupled to a corresponding pin 122P. A first capacitor 124 is connected between the pins 120P and 122P, indicating by way of example that the first capacitor 124 may be an external device, with a capacitance that may be selected based on end application and/or converter specifications. The second switching pair 118 includes a third switch 118_1 and a fourth switch 118_2, both controlled by a same pump switching signal SWpmp from the converter controller 100_CC. A first terminal of the third switch 118_1 is connected to the first node 120, and a second terminal of the third switch 118_1 is connected to a third node 126, which provides the high voltage rail voltage (Vhvrail) for the converter 100. A first terminal of the fourth switch 118_2 is coupled to the second node 122, and a second terminal of the fourth switch 118_2 is connected to a fourth node 128, to which is also coupled a corresponding pin 128P. Generally, the controller 100_CC asserts either SWchg or SWpmp at a time, so corresponding only one set of the first switching pair 116 or the second switching pair 118 is closed at a time. For example, first in a charge mode, Swchg is asserted (i.e., logic 1 state) and in response the first switching pair 116 is closed, while the second switching pair 118 is open, and Vregn is coupled by the first switching pair 116 to the first capacitor 124. Second, in a pump mode, Swpmp is asserted and in response the second switching pair 118 is closed, while the first switching pair 116 is open, and the charge across the first capacitor 124 (from the earlier coupling to Vregn) is pumped through the second switching pair 118 to the remainder of the circuit, thereby providing the upper rail voltage Vhvaril. In an example, each of the charge and pump modes is performed before each switched transition of the conductive path that includes the first through fourth power transistors 108_1 through 108_4, with those transitions further described below in connection with FIGS. 2 and 3. Lastly, a second capacitor 130 is also connected between the third node 126 and the fourth node 128. The second capacitor 130 also may have a capacitance that may depend on various factors, and it may be internal to the IC of the converter 100. Accordingly, the second capacitor 130 receives the voltage Vregn from the second switching pair 118 when Swpmp is asserted as described above.

In the first driver circuit 106_1, the first driver 110_1 has a positive power supply terminal coupled to the third node 126 and a negative power supply terminal coupled to the fourth node 128. An input of the first driver 110_1 is coupled to receive a switching signal 132_SS1 from the converter controller 100_CC. The output of the first driver 110_1 is coupled to the gate of the first power transistor 108_1. The first driver 110_1 (as with other drivers described below) generally represents a collection of devices, such as inverters/level shifters, for generating a sufficiently amplified drive current signal to reliably enable its respective power transistor, that is, the first power transistor 108_1, when timed to do so by the state of the switching signal 132_SS1. The drain of the first power transistor 108_1 is connected to receive Vin, and the source of the first power transistor 108_1 is connected to the fourth node 128.

In the second gate driver circuit 106_2, the second driver 110_2 has a positive power supply terminal coupled to a fifth node 134, which is coupled to a corresponding pin 134P. The second driver 110_2 has a negative power supply terminal coupled to ground. A power source 136, such as equal to 5.0 V, is coupled between the fifth node 134 and ground, where the power source 136 may be internal or external and provided by Vregn. An input of the second driver 110_2 is coupled to receive a switching signal 132_SS2 from the converter controller 100_CC. The output of the second driver 110_2 is connected to the gate of the second power transistor 108_2. The drain of the second power transistor 108_2 is connected to a sixth node 138, and the source of the second power transistor 108_2 is connected to ground.

In the third gate driver circuit 106_3, the third driver 110_3 has a positive power supply terminal connected to a first high output node 140 of a first voltage regulator 142, and the third driver 110_3 has a negative power supply terminal connected to a seventh node 144, which is connected to the source of the third power transistor 108_3 and provides a Vsw signal. Accordingly, the first voltage regulator 142 operates to provide sufficient supply to the third driver 110_3, so the gate signal it provides to the third power transistor 108_3 is sufficient relative to the source of that transistor, especially because the potential at that source can vary. The seven node 144 is also connected, and provides the Vsw signal, to a second terminal of the inductor 104. The first voltage regulator 142 includes a first resistor 146 having a first terminal connected to the third node 126 and a second terminal connected to an eighth node 148. The eighth node 148 is further connected to the gate of a first FET 150 and to the cathode of a first Zener diode 152, which has its anode connected to the seventh node 144. The drain of the first FET 150 is connected to the third node 126, and the source of the first FET 150 is connected to the first high output node 140. Accordingly, a source follower (or common drain) configuration is provided, so the output voltage at the first high output node 140 is the voltage across the first Zener diode 152 (approximately 6.0 V) minus the gate-to-source voltage (Vgs) across the first FET 150 (approximately 0.8 V), providing a sufficiently high supply voltage (approximately 5.2 V) to the positive supply of the third driver 110_3. A regulator first capacitor 154 is connected between the first high output node 140 and the seventh node 144. The regulator first capacitor 154 stabilizes the voltage between the first high output node 140 and the seventh node 144 during transient, that is, when current is drawn by the third driver 110_3 from the first high output node 140. The output of the third driver 110_3 is connected to the gate of the third power transistor 108_3. The drain of the third power transistor 108_3 is connected to the fourth node 128, and the source of the third power transistor 108_3 is connected to the seventh node 144.

In the fourth gate driver circuit 106_4, the fourth driver 110_4 has a positive power supply terminal connected to a first high output node 156 of a second voltage regulator 158, and the fourth driver 110_4 has a negative power supply terminal connected to a low output node 160, which is connected to the source of the fourth power transistor 108_4 (hence, the same as the sixth node 138). As described below, the second voltage regulator 158 is also coupled to the third node 126 (to receive Vhvrail), and it operates to provide sufficient supply to the fourth driver 110_4, so the gate signal it provides to the fourth power transistor 108_4 is sufficient relative to the source of that transistor, especially because the potential at that source can vary. Also, the voltage difference applied across the voltage regulator, between the third node 126 and the source of the fourth power transistor 108_4, can be relatively large, and can vary, based on the on/off switching of the various power transistors 108_1 through 108_4. For example, at times when the first power transistor 108_1 is on, it coupled Vin to the fourth node 128, which can then add to the voltage across the second capacitor 130 to considerably increase Vhvrail (e.g., to 20 to 25 V). Accordingly, the voltage regulator 158 is improved, as described below, to mitigate potential voltage loss from the Vhvrail swings, especially as such losses may be considerable in conventional devices that implement solely a linearly regulator, which can be especially lossy, to drive a power transistor, with a source that can change voltage and situated with its source/drain path in series with the source/drain paths of two or more additionally switched power transistors. A flying capacitor 162 is coupled between the fourth node 128 (or its pin 128P) and a low reference potential input 164 (or its pin 164P) of the second voltage regulator 158. A separate charge circuit 166 is shown generally connected by dashed lines, between the second node 122 and the low reference potential input 164, to illustrate that the charge circuit 166 may be switched into a path to charge the flying capacitor 162, generally to a voltage of Vin/2 before the additional switching operation of level-determining circuits 106_1, 106_2, 106_3, and 106_4. As described below, this charged voltage provides a middle voltage level among the three voltage level outputs, which are Vin, ground, and Vin/2 (the voltage across the flying capacitor 162). The second voltage regulator 158 also receives, and operates responsive to, a control signal REG CTRL from one or more nodes, described below, associated with the second driver 110_2 and along a control node 168. The output of the fourth driver 110_4 is connected to the gate of the fourth power transistor 108_4. The drain of the fourth power transistor 108_4 is connected to the seventh node 144, and the source of the fourth power transistor 108_4 is connected to the sixth node 138. Accordingly, and as also described below, the second voltage regulator 158 responds to REG CTRL by providing a robust supply to the fourth driver 110_4, further supporting the drive signal to the fourth power transistor 108_4. The operation of the fourth power transistor 108_4 is thereby improved, which otherwise could be vulnerable as its source potential, at the sixth node 138, can vary away from ground and thereby affect source-to-drain potential, especially during periods when the DC-DC converter 100 duty cycle D is below 50 percent.

FIG. 2 is a switching diagram 200 illustrating DC-DC converter 100 operation and signal timing when the converter duty cycle, D, is less than 50%. The bottom of FIG. 2 illustrates two timing diagrams, each with switching duration Tsw along the horizontal axis, and with a separate and vertical axis corresponding to Vsw and iL, respectively, during the Tsw duration. The top of FIG. 2 illustrates the conductive path through portions of the first through fourth power transistors 108_1, 108_2, 108_3, and 108_4, and the flying capacitor 162, corresponding to each of a first through fourth respective switched interval 202, 204, 206, and 208. For each switched interval, as introduced above (but not shown in FIG. 2), first each of the charge and pump modes occurs to provide power to Vhvrail (see FIG. 1), and then two of the four power transistors are on and concurrently the other two complementary of the four power transistors are off, with the off transistors shown in dotted lines and the on shown in solid, so as to illustrate the resultant conductive path through the on transistors. Also, control to turn on and off the corresponding transistors is accomplished by the controller 100_CC and its control signals 132_SS1 through 132_SS4, to the respective gate drivers 110_1 through 110_4 (see FIG. 1), for each corresponding switched interval. Generally, the first and third switched intervals 202 and 206 have a same first duration and provide a relatively high voltage Vsw, and the second and fourth switched intervals 204 and 208 have a same second duration and provide a relatively low voltage Vsw. Further, D is the ratio of the total duration of the time when the first power transistor 108_1 is on, which in FIG. 2 is shown as the first interval 202, relative to the total period of Tsw. Accordingly, in the FIG. 2 example, that ratio is such that D is less than 50%.

During the first interval 202, the first and fourth power transistors 108_1 and 108_4 are on, while the second and third power transistors 108_2 and 108_3 are off. Accordingly, Vsw equals the Vin minus the pre-charged voltage across the flying capacitor 162 (of Vin/2), so that Vsw is approximately Vin/2. With Vsw at this approximate voltage for the duration of the first interval 202, and with Vsw having been lower at an earlier interval not shown, iL rises to store energy into the FIG. 1 inductor 104 for that interval.

During the second interval 204, the second and fourth power transistors 108_2 and 108_4 are on, while the first and third power transistors 108_1 and 108_3 are off. Accordingly, Vsw is connected through the on transistors (108_2 and 108_4) to ground. With Vsw at ground, iL falls and the previously stored inductor energy from the first interval 202 is transferred to the output, including both the output capacitor 102 and usually a load (not shown) coupled to that output.

During the third interval 206, the second and third power transistors 108_2 and 108_3 are on, while the first and fourth power transistors 108_1 and 108_4 are off. Accordingly, Vsw equals the precharged voltage across the flying capacitor 162 (of Vin/2), so that Vsw is approximately Vin/2. Again, therefore, with Vsw at this approximate voltage for the duration of the third interval 206, iL rises to store energy into the inductor 104 for that interval.

During the fourth interval 208, the power transistors are controlled in the same manner as the second interval, namely, the second and fourth power transistors 108_2 and 108_4 are on, while the first and third power transistors 108_1 and 108_3 are off. Accordingly, again Vsw is connected through the on transistors to ground. Again, therefore, iL falls and the previously stored inductor energy from the third interval 206 is transferred to the output, including both the output capacitor 102 and the load.

FIG. 3 is a switching diagram 300, using comparable conventions to FIG. 2, but FIG. 3 illustrates the DC-DC converter 100 operation and signal timing when the converter duty cycle, D, is greater than 50%. The FIG. 3 bottom again illustrates two timing diagrams, each with switching duration Tsw along the horizontal axis, and one with vertical axis of Vsw and the other oxer with vertical axis iL, during the Tsw duration. The FIG. 3 top illustrates the conductive path through portions of the first through fourth power transistors 108_1, 108_2, 108_3, and 108_4, and the flying capacitor 162, corresponding to each of a first through fourth respective switched interval 302, 304, 306, and 308. The first and third switched intervals 302 and 306 have a same first duration and provide Vsw as a relatively low voltage, and the second and fourth switched intervals 304 and 308 have a same second duration and provide Vsw as a relatively high voltage. Again D is defined as the ratio of the time(s) when the first power transistor 108_1 is on relative to the total period of Tsw, so in FIG. 3, D is determined by the total duration of the first, second, and fourth switched intervals 302, 304, and 308 to the total period of Tsw, so that the FIG. 3 example demonstrates that D is greater than 50%.

During the first interval 302, the first and fourth power transistors 108_1 and 108_4 are on, while the second and third power transistors 108_2 and 108_3 are off. Accordingly, Vsw equals Vin minus the precharged voltage across the flying capacitor 162 (of Vin/2), so that Vsw is approximately Vin/2. With Vsw at this approximate voltage for the duration of the first interval 302, and with Vsw having been higher at an earlier interval not shown and to thereby cause iL to storage energy to the FIG. 1 inductor 104, then the relative change in level causes iL to fall and previously stored inductor energy in the inductor to transfer to the output, including both the output capacitor 102 and usually a load (not shown) coupled to that output.

During the second interval 304, the first and third power transistors 108_1 and 108_3 are on, while the second and fourth power transistors 108_2 and 108_4 are off. Accordingly, Vsw is connected through the on power transistors (108_1 and 108_3) to Vin. With Vsw equal to Vin, iL rises to store energy into the FIG. 1 inductor 104 for the second interval 304.

During the third interval 306, the second and third power transistors 108_2 and 108_3 are on, while the first and fourth power transistors 108_1 and 108_4 are off. Accordingly, Vsw equals the precharged voltage across the flying capacitor 162 (of Vin/2), so that Vsw is approximately Vin/2. Again, therefore, with Vsw at this approximate voltage for the duration of the third interval 306, then the relative change in level from the second interval 304 causes iL to fall and the previously stored inductor energy in the inductor to transfer to the output, including both the output capacitor 102 and usually the load coupled to that output.

During the fourth interval 308, the power transistors are controlled in the same manner as the second interval, namely, the first and third power transistors 108_1 and 108_3 are on, while the second and fourth power transistors 108_2 and 108_4 are off. Accordingly, again Vsw is connected through the on transistors to ground. Accordingly, with Vsw equal to Vin, iL rises to store energy into the FIG. 1 inductor 104 for the fourth interval 308.

Having described the timing of the control signals and switching achieved through each of the respective gate drivers 110_1 through 110_4 and corresponding power transistors 108_1 through 108_4, reference is made to the supply differentials provided to those gate drivers 110_1 through 110_4. Generally, the supply differential to each respective gate driver is desirably high enough to fully enable the power transistor respectively driven by the gate driver, and more particularly with consideration of the drain-to-source voltage of that power transistor. Further, the drain-to-source voltage may vary where the source of the power transistor that is being driven is floating, so various of the aspects described below are implemented in this regard, so as to ensure that for a given power transistor source voltage, its gate signal (and the driver providing that signal) are adequate to achieve desirable operation and efficiency.

Returning to FIG. 1, with respect to the first gate driver 110_1, it receives a power supply differential between the third node 126 (by Vhvrail) and the fourth node 128, which is also connected to the source of the first power transistor 108_1. Regarding Vhvrail, before the switching of FIG. 2 or 3 occurs, Vregn is coupled through the first switching pair 116 and stored across the first capacitor 124, where Vregn may be a voltage generated internally within the converter 100, such as Vregn=5.0 V. After the first capacitor 124 is so charged, the controller 100_CC opens the first switching pair 116 and concurrently closes the second switching pair 118, thereby coupling the Vregn charge from across the first capacitor 124 to the third node 126. That voltage adds to the voltage at the fourth node 128, so Vhvrail=Vregn plus the voltage at the fourth node 128. In this manner, the first capacitor 124 is a bootstrap capacitor, in that it temporarily stores voltage and the voltage it stores is essentially added to the fourth node 128 (the source of the first power transistor 108_1), bootstrapping to that voltage so that Vhvrail is that amount of voltage (e.g., 5.0 V) higher than the fourth node 128. Accordingly, the gate driver 110_1 is sufficiently biased between Vhvrail and the fourth node 128.

With respect to the third gate driver 110_3, it receives a power supply differential from the first voltage regulator 142, and more particularly between the first high output node 140 and the seventh node 144. The first voltage regulator 142 operates as a linear regulator with respect to Vhvrail, so it receives Vhvrail and provides a regulated voltage relative to it based on the first Zener diode 152. Specifically, Vhvrail is connected through the first resistor 146 to the cathode of the first Zener diode 152, which has a controlled breakdown voltage, such as approximately 6.0 V that is applied to the gate of the first FET 150, even if (or when) Vhvrail varies. Accordingly, if approximately 0.8 V is dropped across the gate-to-source of the first FET 150, then its source provides approximately 5.2 V (as a source follower), thereby supplying that potential to the positive supply of the third gate driver 110_3, and with the first Zener diode 152 anode providing a relative low potential to the negative supply of the third gate driver 110_3 and to the source of the third power transistor 108_3. Further, if Vsw changes values at the seventh node 144, then the relative change occurs at the source of the third power transistor 108_3, and also to the anode of the first Zener diode 152; accordingly, the latter causes the same breakdown voltage (e.g., 6.0 V) to add as a positive offset to the Vsw change, again providing an adequate positive voltage supply to the third gate driver 110_3 and an adequate drive signal to the third power transistor 108_3.

With respect to the fourth gate driver 110_4, it receives a power supply differential from the second voltage regulator 158, and more particularly between the first high output node 156 and the low output node 160. In an example, the second voltage regulator 158 includes aspects either differing from, or in addition to, a linear voltage regulator (for example, as used in this example for the first voltage regulator 142), to improve upon the potential inefficiencies, such as power dissipation, that sometimes are incurred with a linear voltage regulator, especially for potentially larger voltage levels across the regulator. For example, FIG. 2 illustrates that when D<50% and in the first interval 202, a voltage of approximately Vin/2 may be applied across fourth power transistor 108_4, while its source is not connected to ground and it is driven by the corresponding fourth gate driver 110_4. Further, for a fixed Vout, as D decreases, Vin increases. The relatively larger Vin raises the voltage at the fourth node 128 (at the source of the first power transistor 108_1), and accordingly also Vhvrail, with a resultant larger current draw from Vhvrail which will induce a current draw from the flying capacitor 162, which stores Vin/2. Also, energy loss from Vhvrail is a draw on Vregn, via the charge/pump operation of the first switching pair 116 and the second switching pair 118. Accordingly, the second voltage regulator 158 addresses such potential inefficiencies, as described below.

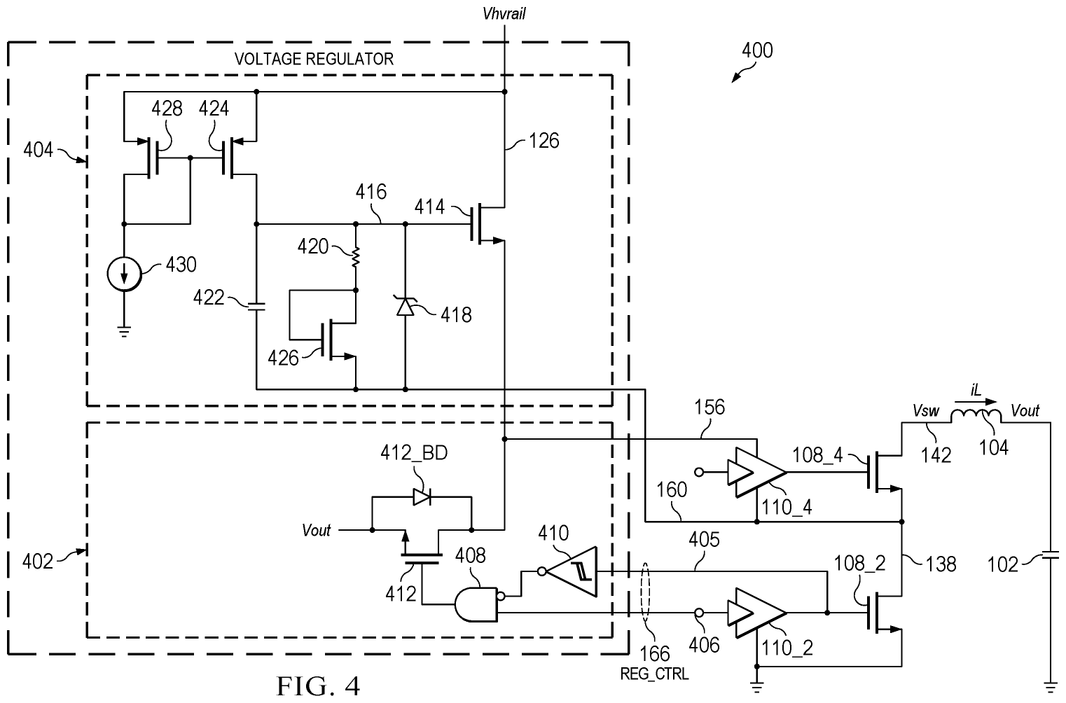

FIG. 4 is a schematic electrical diagram of a first implementation 400 of the FIG. 1 second voltage regulator 158, along with the REG CTRL control of it from the second gate driver 110_2. The first implementation 400 includes two alternative power supply sources from which power may be switchably selected and coupled to a power transistor driver, namely: (i) a first bypass voltage source 402 which in certain operations provides a high side supply voltage to the fourth gate driver 110_4; and (ii) a first linear regulator voltage source 404 which in other operations provides the high side supply voltage to the fourth gate driver 110_4. Each of the voltage sources 402 and 404 is described below.

The first bypass voltage source 402 receives the REG CTRL signal from the second gate driver 110_2, and the FIG. 4 example expands the FIG. 1 control node 168 to include two separate control signal lines. A first control signal line 405 is connected to the output of the second gate driver 110_2, and a second control signal line 406 is connected to the input of the second gate driver 110_2. The first control signal line 405 is also connected as an input to an inverting Schmitt trigger 410, and the output of the inverting Schmitt trigger 410 is connected to an inverting input of an AND gate 408. The second control signal line 406 is also connected to a non-inverting input of an AND gate 408. The output of the AND gate 408 is connected to the gate of an n-channel field-effect transistor (NFET) 412, having a back diode 412_BD. The source of the NFET 412 is connected to receive Vout, or alternatively it may be connected to receive Vregn. The drain of the NFET 412 is connected to the first high output node 156, which is also connected to the positive power supply terminal of the fourth gate driver 110_4.

The first linear regulator voltage source 404 includes an NFET 414 with its drain connected to the third node 126 to receive Vhvrail and its source connected to the high output node 156 and thereby to the positive supply terminal of the fourth gate driver 110_4. The gate of the NFET 414 is connected to a first drive node 416. The first drive node 416 is connected to the cathode of a second Zener diode 418, a first terminal of a second resistor 420, a first terminal of a fourth capacitor 422, and the drain of a p-channel field-effect transistor (PFET) 424. The source of the PFET 424 is connected to the third node 126. The anode of the second Zener diode 418, and the second terminal of the fourth capacitor 422, are connected to the low output node 160 (see also FIG. 1), which is connected to the negative power supply of the fourth gate driver 110_4 and the source of the fourth power transistor 108_4. The second terminal of the second resistor 420 is connected to a drain and gate of an NFET 426, which in an example is matched to the NFET 414 and has its source connected to the low output node 160. The gate of the PFET 424 is connected to the gate and drain of a PFET 428, which has its source connected to the third node 126. The drain of the PFET 428 is also connected to the input of a current source 430, which has its output connected to ground.

The operation of the first implementation 400 includes the conditional provision, switching between either the first bypass voltage source 402 or the first linear regulator voltage source 404, as a primary power supply source to the fourth gate driver 110_4 at a time. Accordingly, during some time periods, at least a majority of the supply power is provided by the first bypass voltage source 402, while during other time periods, at least a majority of the supply power is provided by the first linear regulator voltage source 404. In an example, generally the selection between supply sources is implemented via the switching (enabled/disabled) operation of the NFET 412, and the condition is indicated by a signal state, such as provided by the AND gate 408. In more detail, when the second power transistor 108_2 is on, the first bypass voltage source 402 may be the primary supply to the fourth gate driver 110_4, if the fourth gate driver 110_4 is enabled at that time to drive its respective fourth power transistor 108_4. Conversely, when this condition is not satisfied, that is when the second power transistor 108_2 is off, the linear voltage source 404 may be the primary supply to the fourth gate driver 110_4, if the fourth gate driver 110_4 is enabled at that time to drive its respective fourth power transistor 108_4. Each of those alternatives is further described below.

Operation of the first bypass voltage source 402 as the primary supply to the fourth gate driver 110_4 is described, for example, with reference to the FIG. 2 switched intervals, which occur when D<50%. During the second, third, and fourth switched intervals 204, 206, and 208, the second power transistor 108_2 is on, and among those three switched intervals, during the second and fourth switched intervals 204 and 208, the fourth power transistor 108_4 is also to be on and, accordingly, requires a driving gate signal from the respective fourth gate driver 110_4. Given that the second power transistor 108_2 is on, as described above in connection with FIG. 4, REG CTRL is provided by two control signals that will be asserted when that transistor 108_2 is on, as one of the two control signals (406) logically enables the second gate driver 110_2 and the other (405) is representative of the output of that second gate driver 110_2. Those two signals pass to the combined logic of the Schmitt trigger 410 and AND gate 408, so after the delay of the signal rising to the threshold input of the Schmitt trigger 410, the output of the AND gate 408 will rise and, as applied to the gate of the NFET 412, will enable that NFET 412. Accordingly, Vout is coupled through the enabled source/drain path of the enabled NFET 412 and to the first high output node 156, thereby providing Vout to the positive power supply terminal of the fourth output driver 110_4 (meanwhile, because the second power transistor 108_2 is on during that time, it grounds the negative power supply terminal of the fourth output driver 110_4). Further, because the first bypass voltage source 402 is only enabled in this manner to overlap the time when the second power transistor 108_2 is on, at that same time the enabled source/drain path of that second power transistor 108_2 concurrently couples the negative power supply of the fourth output driver 110_4, and the source of the fourth power transistor 108_4, to ground

In view of the description above, during the condition when the second power transistor 108_2 is on and the fourth gate driver 110_4 is required to drive the fourth power transistor 108_4, the first bypass voltage source 402 provides a satisfactory differential drive power, between Vout and ground, to the fourth output driver 110_4, as opposed to providing drive power from a linearly-regulated voltage, providing the upper rail of that drive power. Such an approach is sufficient, if not favorable, because, in the conditions satisfied, when the power transistor 108_4 is turned on, its source will not be floating, but instead will be grounded by the concurrent enabled operation of the second power transistor 108_2. Accordingly, in the example, not only is Vout provided and sufficient when the power transistor 108_4 is turned on with its source grounded, but the same applies when it is turned off. For example, as described above in connection with FIG. 2, D<50%, which may occur when Vin is relatively high. Also in FIG. 2, as shown in the transition from the second switched interval 204 to the third switched interval 206, the power transistor 108_4 is turned off, while its source is grounded through the second power transistor 108_2. Accordingly, when D<50%, in each instance when the state of the fourth power transistor 108_4 is to be switched, either from off to on or on to off, and with that switching operation driven by its corresponding gate driver 110_4, then instead of a potentially large voltage drop from Vhvrail having to supply the positive supply terminal of that gate driver 110_4 through a lossy linear regulator, the gate driver 110_4 is driven by a more efficient voltage, such as either Vout or Vregn. Such operation may reduce the potential inefficiencies, such as significant driver losses, as may occur in an approach in which a variable (e.g., linearly regulated) supply voltage is applied to the fourth output driver 110_4.

During the period when the first bypass voltage source 402 is enabled and provides Vout to the positive supply terminal of the gate driver 110_4, the first linear regulator voltage source 404, while not providing a majority of output power, also has some signal activity. For example, Vhvrail is coupled to the third node 126, and thereby to the source of each of the PFET 424 and PFET 428, and those transistors form a current mirror in combination with the current source 430. Accordingly, current passes through the source/drain path of the PFET 424, the second resistor 420, and the third (diode-connected) NFET 426, creating a voltage drop across the second resistor 420 and the NFET 426. In an example, the anticipated current from the current mirror, and selected resistance value of the second resistor 420, provide a total voltage approaching, but below, the required Vgs to enable the NFET 414. For example, at that same time, the Vout from the first bypass voltage source 402 to the first high output node 156 is also coupled to the source of NFET 414, so the Vgs to enable the NFET 414 is necessarily relative the Vout source voltage at the first high output node 156. Meanwhile, the combined voltage drop across the second resistor 420 (e.g., 3.8 V), and across the diode-connected NFET 426 (e.g., 0.7 V) that is matched to the NFET 414, is kept at approximately Vout, or slightly below, such as at a voltage of 4.5 V, and that voltage applies a gate bias to the NFET 414. Accordingly, the gate and source voltages for the NFET 414 are approximately the same, which is insufficient to surpass the transistor threshold voltage and accordingly does not enable the NFET 414 during the period when the first bypass voltage source 402 is enabled. However, this non-zero voltage is desirably very close in margin (e.g., 100 mV to 200 mV) below the threshold voltage of the NFET 414, and it is maintained while the first bypass voltage source 402 is enabled. Accordingly, after the voltage from the first bypass voltage source 402 to the first high output node 156 falls below that margin, the NFET 114 can be turned on quickly, such as relative to a much larger turn on time as would be needed if the gate voltage were rising from zero. That relatively quick turn-on may occur when the output of the AND gate 408 is not asserted (i.e., changes from logic 1 state to logic 0 state) and as described below, such as when switching the second power transistor 108_2 from on to off (or off to on). Moreover, with the NFET 414 disabled in this manner, it does not draw current that could otherwise deplete charge stored on the second capacitor 130 (see FIG. 1, coupled toVhvrail). With respect to remaining items in the first linear regulator voltage source 404, the fourth capacitor 422 is a decoupling capacitor to stabilize the combined voltage drop across it (between nodes 416 and 160), such as due to changes at the low output node 160 that can occur by way of the connection to the source of the fourth power transistor 108_4 and when voltage in the first linear regulator voltage source 404 ramps up from Vhvrail to supply the fourth driver 110_4, as also described below. Lastly, the second Zener diode 418 is generally a protective device, which does not break down during normal operation. The second Zener diode 418, however, may break down if the voltage at the first drive node 416 rises too high, such as from switching noise or if the current source 430 is not set properly; in either of those instances, breakdown of the second Zener diode 418 ensures that the Vgs across the NFET 414 is desirably limited.

Operation of the first linear regulator voltage source 404 as the primary supply to the fourth gate driver 110_4 is described, for example, when the fourth power transistor 108_4 is on, while the second power transistor 108_2 is not, in the same switched interval. A first example of those conditions occurs in the FIG. 2 first switched interval 202, in which D<50%. In the transition to the FIG. 2 first switched interval 202, from the immediately preceding fourth switched interval 208, the second power transistor 108_2 transitions off, while the fourth power transistor 108_4 is to remain on during that transition. Accordingly, the fourth gate driver 110_4 continues to receive an enabling signal so as to continue to drive the fourth power transistor 108_4, and its positive power supply terminal pulls down the voltage at the first high output node 156, that is, at the source of the NFET 414. Meanwhile, as shown in the FIG. 2 first switched interval 202, the voltage at the source of the fourth power transistor 108_4 is approximately Vin/2, and the voltage across the combination of the second resistor 420 and the third (diode-connected) NFET 426 (e.g., 3.8 V and 0.7 V, respectively) adds to that source voltage. Accordingly, this total voltage (e.g., 4.5 V) is applied to the transistor 414 gate, while its source is concurrently pulled downward to effectively increase its Vgs, with the resultant Vgs being sufficiently larger than the transistor threshold voltage, thereby turning on the transistor 414 so that it provides power from Vhvrail to the first high output node 156 and thereby also to the positive power supply terminal of the fourth gate driver 110_4. A second example of the conditions of the second power transistor 108_2 off while the fourth power transistor 108_4 is on occurs in the FIG. 3 first switched interval 302, in which D>50%. Here, in the transition to the first switched interval 302, from the immediately preceding fourth switched interval 308, the fourth gate driver 110_4 receives an enabling signal so as to transition the fourth power transistor 108_4 from off (in the fourth switched interval 308) to on (in the first switched interval 302). Accordingly, the fourth gate driver 110_4 pulls down on the source of the NFET 414, while concurrently again the combined voltage, across the second resistor 420 and the third (diode-connected) NFET 426, biases its gate, so that a resulting Vgs exceed its threshold voltage, thereby turning on the transistor 414 which provides power from Vhvrail to the positive power supply terminal of the fourth gate driver 110_4.

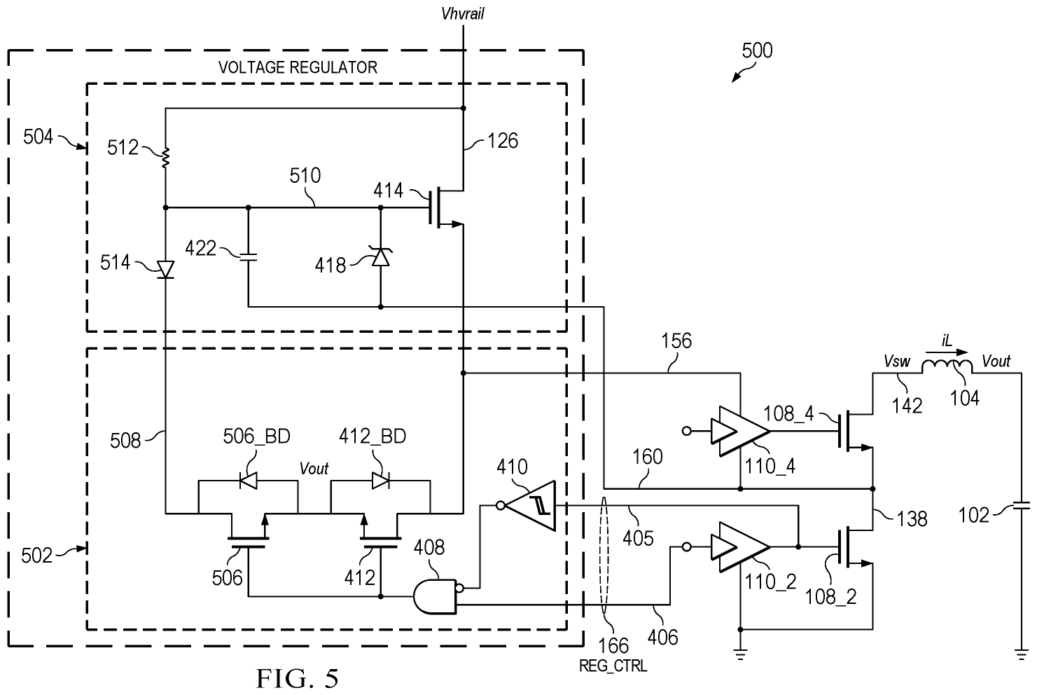

FIG. 5 is a schematic electrical diagram of a second implementation 500 of the FIG. 1 second voltage regulator 158. The second implementation 500 shares some of the same items and connections as the FIG. 4 first implementation 400, for which like reference numbers are used in both FIGS. 4 and 5. The second implementation 500 includes a second bypass voltage source 502, which provides a high side supply voltage to the positive power supply terminal of the fourth gate driver 110_4 when the second power transistor 108_2 is to be on, and a second linear regulator voltage source 504, which in other operations may provide the high side supply voltage to the fourth gate driver 110_4. Each of the voltage sources 502 and 504 is described below.

The second bypass voltage source 502 is similar to the above-described first bypass voltage source 402 (FIG. 4), because the REG CTRL signal lines are coupled to the same logic combination of the AND gate 408 and the Schmitt trigger 410, and the output of the AND gate 408 is connected to the gate of the NFET 412. The second bypass voltage source 502 also includes an NFET 506, with its source connected to the source of the NFET 412 (and also to receive Vout or Vregn), its gate connected to the output of the AND gate 408, its drain connected to an ninth node 508, and having a back diode 506_BD. The ninth node 508 is also coupled to the second linear regulator voltage source 504 which, as described below, facilitates an adaptive gate bias to its NFET 414.

The second linear voltage source 504 is similar to the above-described first linear voltage source 404 (FIG. 4), because both include the NFET 414, the second Zener diode 418, and the fourth capacitor 422, where the anode of the second Zener diode 418 and a first terminal of the fourth capacitor 422, are both connected to the low output node 160. The cathode of the second Zener diode 418, and a second terminal of the fourth capacitor 422, are both connected to a tenth node 510, which is also coupled to the gate of the NFET 414. A third resistor 512 is connected between the tenth node 510 and the third node 126. The anode of a diode 514 is connected to the tenth node 510, and the cathode of the diode 514 is connected to the ninth node 508.

Operation of the second bypass voltage source 502 and the second linear voltage source 504 is similar to operation of the first bypass voltage source 402 and the first linear voltage source 404 (FIG. 4). However, the linearly-regulated voltage provided in FIG. 5 is, in part, responsive to the output of the AND gate 404. For example, when the AND gate 404 output is asserted, it enables the NFET 412 as described above, and concurrently it enables the NFET 506, thereby coupling Vout to the ninth node 508. Accordingly, Vout is coupled to the cathode of the diode 514, so the voltage at the anode of that diode 514 is one diode drop larger, and that anode voltage is applied to the gate of the NFET 414. At the same time, Vout is coupled through the enabled NFET 412 to the source of the NFET 414. Accordingly, the NFET 414 has Vout at its source, and Vout plus the diode drop across the diode 514 at its gate, and the diode 514 is selected such that its diode drop is less than the threshold voltage of the NFET 412. Accordingly, the NFET 414 turns off fairly quickly when the output of the AND gate 408 is asserted, so that the NFET 414 does not provide supply to positive power supply terminal of the fourth driver 110_4, which instead is provided at that time through the NFET 412. However, although the NFET 414 remains off, its gate voltage during that time is maintained at well-controlled level which, after the output of AND gate 408 is no longer asserted (i.e., changes from logic 1 state to logic 0 state), that level can be quickly and efficiently raised by Vhvrail to a higher level that will enable the NFET 414, at times when it is required to provide a supply voltage to the first high output node 156.

The illustrated examples provide a DC-to-DC converter with switching of level-determining circuits to provide Vout, such as based on Vin and D. Each of the level-determining circuits includes a transistor (e.g., power transistor) and a driver to that transistor. In an example, the driver of a first level circuit is provided power responsive to the conditional state of the driver in a second, and different, level circuit. Also in an example, a same power transistor driver is supplied alternate power supply sources under different operating conditions. Also in an example, the first level circuit is provided linearly-regulated power when the second level circuit is in a non-conducting state and non-linearly regulated power when the second level circuit is in a conducting state. Accordingly, potential inefficiencies that may arise from linearly-regulated power are mitigated during periods when non-linearly regulated power are provided. Various details and implementations are provided, and still others are contemplated. For example, while FIG. 1 illustrates a buck converter configuration, examples herein may be incorporated into a boost converter configuration (e.g., by using Vout at the input and Vin as the output). As another example, while FIGS. 3 and 4 both illustrate Vout as a source of the bypass voltage to the NFET 412 (and in FIG. 4 also to the NFET 506), in an alternative example another potential may be used, such as Vregn. In comparing the use of Vout or Vregn, in some implementations Vout may be more efficient, as Vout is related to the switching voltage Vsw, while Vregn may be linearly generated in the system and based on available system power, including for example consideration of a relatively large Vin (e.g., Vin at 20.0 V or higher), in which case the step down from Vin to Vregn is a relatively large percentage. Accordingly, another alternative may be to selectively bias the bypass first from Vregn during startup, such as if Vout is not then sufficient to provide the bypass bias, then switching from Vregn to Vout as the bypass after the startup is complete.

Modifications are possible in the described embodiments, and other embodiments are possible, within the scope of the claims.

What is claimed is:

1. A switched circuit, comprising:
first and second transistors, in which the first transistor has a first gate and a first source/drain path, the second transistor has a second gate and a second source/drain path, and the first and second source/drain paths are coupled in series between an input terminal and an output terminal;
first and second drive circuits, in which the first drive circuit has a first drive input and a first drive output, the second drive circuit has a second drive input and a second drive output, the first drive output is coupled to the first gate, and the second drive output is coupled to the second gate;
first and second power supply circuits; and
switching circuitry coupled between: at least one of the first or second power supply circuits; and at least one of the first or second drive circuits.

2. The switched circuit of claim 1, wherein the switching circuitry has a control input coupled to the second drive output.

3. The switched circuit of claim 2, wherein the second transistor has a source coupled to a ground terminal.

4. The switched circuit of claim 3, wherein the second drive circuit is configured to provide a gate signal at the second drive output.

5. The switched circuit of claim 3, wherein the control input is a first control input, the second drive circuit has a drive control input, and the switching circuitry has a second control input coupled to the drive control input.

6. The switched circuit of claim 5, wherein:
the switching circuitry includes: a Schmitt trigger having a Schmitt trigger input and a Schmitt trigger output, in which the Schmitt trigger input is coupled to the second drive output; and an AND gate having a non-inverting input, an inverting input and an AND gate output, in which the non-inverting input is coupled to the second control input, and the inverting input is coupled to the Schmitt trigger output; and
the first power supply circuit includes a voltage supply transistor having a gate and a source/drain path, in which the gate is coupled to the AND gate output, and the source/drain path is coupled between a voltage source terminal and the first drive input.

7. The switched circuit of claim 6, wherein the voltage supply transistor is a first voltage supply transistor, the switched circuit comprises regulated power supply circuitry, and the second power supply circuit includes a second voltage supply transistor having a source/drain path coupled between the voltage source terminal and the regulated power supply circuitry.

8. The switched circuit of claim 1, wherein the first power supply circuit includes a linearly-regulated power supply, and the second power supply circuit includes a fixed voltage power supply.

9. The switched circuit of claim 8, wherein the linearly-regulated power supply includes:
a bias transistor having a gate and a source/drain path, in which the source/drain path of the bias transistor is coupled between a rail voltage terminal and the at least one of the first or second drive circuits; and
a series path including a resistor and diode-connected transistor, the series path configured to provide a gate bias to the gate of the bias transistor.

10. The switched circuit of claim 9, wherein the first power supply circuit includes a linearly-regulated power supply, and the second power supply circuit is coupled to the output.

11. The switched circuit of claim 1, wherein the first power supply circuit includes a linearly-regulated power supply, and the second power supply circuit is coupled to the output terminal.

12. The switched circuit of claim 1, wherein the first power supply circuit includes a linearly-regulated power supply, and the second power supply circuit is coupled to a voltage terminal.

13. The switched circuit of claim 1, wherein a voltage at the voltage terminal is responsive to a voltage at the input terminal.

14. The switched circuit of claim 1, further comprising third and fourth transistors, in which the switched circuit is configured to turn on only two of the first, second, third and fourth transistors at a time.

15. The switched circuit of claim 14, wherein the switched circuit is configured to turn on: only one of the first or second transistors at a time; and only one of the third or fourth transistors at a time.

16. The switched circuit of claim 1, wherein the switched circuit is configured to provide a switching output voltage at the output terminal, and the switching output voltage is proportional to: a voltage at the input terminal multiplied by a duty cycle of operation of at least one of the first or second transistors.

17. A voltage converter, comprising:
first and second level determining circuits, in which the first level determining circuit includes a first switching transistor and a first drive circuit, the second level determining circuit includes a second switching transistor and a second drive circuit, the first drive circuit has a first output coupled to the first switching transistor, and the second drive circuit has a second output coupled to the second switching transistor;
first and second power supply sources; and
switching circuitry configured to connect the first power supply source or the second power supply source to the first drive circuit responsive to a conductive state of the second switching transistor.

18. The voltage converter of claim 17, wherein the second drive circuit has a drive input and a drive output, and the switching circuitry is configured to connect the first power supply source or the second power supply source to the first drive circuit responsive to the drive input or the drive output.

19. The voltage converter of claim 17, further comprising third and fourth level determining circuits.

20. The voltage converter of claim 17, wherein the second switching transistor includes a source terminal coupled to a ground terminal.

21. A method of operating a voltage converter, the method comprising:
receiving an input voltage;
during a switching duration including switched intervals, operating first and second level determining circuits to convert the input voltage to a switched output voltage;
during a first switched interval in the switched intervals, coupling a first power supply source to a first driver in the first level determining circuit; and
during a second switched interval in the switched intervals, coupling a second power supply source to the first driver.

22. The method of claim 21, wherein the first power supply source includes a linearly-regulated power supply, and the second power supply source is configured to provide a voltage responsive to the switched output voltage.
